(19) United States
(12) Patent Application Publication
(10) Pub. No.: US 2026/0283016 A1
(43) Pub. Date: Sep. 17, 2026

(54) SEMICONDUCTOR DEVICE

(71) Applicant: Kioxia Corporation, Tokyo (JP)

(72) Inventor: Yuichi SANO, Tokyo (JP)

(73) Assignee: Kioxia Corporation, Tokyo (JP)

(21) Appl. No.: 19/236,455

(22) Filed: Jun. 12, 2025

(30) Foreign Application Priority Data
Mar. 17, 2025 (JP) 2025-042574

(51) Int. Cl. H01L 23/00; H01L 25/16

(52) U.S. Cl. CPC H10W 90/00; H10W 72/59; H10W 90/24; H10W 90/752; H10W 90/754

(57) ABSTRACT

A semiconductor device of an embodiment has: a wiring board having on a surface a plurality of first electrode pads; and a first semiconductor chip mounted on the wiring board, and having on a surface a plurality of second electrode pads; each of the plurality of first electrode pads has at least in a part thereof a first width in a first direction along a face of the wiring board, is arranged side by side in the first direction at a first pitch, and has on a surface a first bump having a second width in the first direction larger than the first width; the plurality of second electrode pads are arranged side by side in the first direction at the first pitch; and each of a plurality of first bonding wires is connected at one end through the first bump to each of the plurality of first electrode pads, and is connected at another end to each of the plurality of second electrode pads.

### CROSS-REFERENCE TO RELATED APPLICATIONS

This application is based upon and claims the benefit of priority from Japanese Patent Application No. 2025-042574, filed on Mar. 17, 2025; the entire contents of which are incorporated herein by reference.

### FIELD

Embodiments described herein relate generally to a semiconductor device.

### BACKGROUND

A semiconductor device having a semiconductor chip mounted on a wiring board has been known. In the semiconductor device, the semiconductor chip and the wiring board are electrically connected, typically by connecting a plurality of electrode pads individually owned by the semiconductor chip and the wiring board, with bonding wires.

The electrode pads on the wiring board are arranged at a relatively large pitch as compared with the electrode pads on the semiconductor chip having a fine pitch, in order to suppress short-circuiting between the electrode pads. Misalignment therefore occurs between the arrangement of the electrode pads on the semiconductor chip and the arrangement of the electrode pads on the wiring board, so that the electrode pads on the semiconductor chip are connected, by diagonally extending therefrom bonding wires, to the electrode pads on the wiring board.

### BRIEF DESCRIPTION OF THE DRAWINGS

FIG. 1 is a schematic diagram illustrating an exemplary overall structure of a semiconductor device according to an embodiment;

FIGS. 2A to 2F are schematic diagrams illustrating connection modes among semiconductor chips and a wiring board owned by the semiconductor device according to the embodiment;

FIGS. 3A to 3C are cross-sectional views sequentially exemplifying a part of procedures of a method for manufacturing the semiconductor device according to the embodiment;

FIGS. 4A to 4C are cross-sectional views sequentially exemplifying a part of procedures of the method for manufacturing the semiconductor device according to the embodiment;

FIGS. 5A to 5F are cross-sectional views sequentially exemplifying a part of procedures of the method for manufacturing the semiconductor device according to the embodiment;

FIGS. 6A to 6F are cross-sectional views sequentially exemplifying a part of procedures of the method for manufacturing the semiconductor device according to the embodiment;

FIGS. 7A to 7H are cross-sectional views sequentially exemplifying a part of procedures of the method for manufacturing the semiconductor device according to the embodiment;

FIGS. 8A to 8E are cross-sectional views sequentially exemplifying a part of procedures of the method for manufacturing the semiconductor device according to the embodiment;

FIG. 9 is a cross-sectional view sequentially exemplifying a part of procedures of the method for manufacturing the semiconductor device according to the embodiment;

FIGS. 10A to 10C are cross-sectional views sequentially exemplifying a part of procedures of the method for manufacturing the semiconductor device according to the embodiment;

FIGS. 11A to 11C are cross-sectional views sequentially exemplifying a part of procedures of the method for manufacturing the semiconductor device according to the embodiment;

FIGS. 12A to 12C are cross-sectional views sequentially exemplifying a part of procedures of the method for manufacturing the semiconductor device according to the embodiment;

FIGS. 13A to 13C are cross-sectional views sequentially exemplifying a part of procedures of the method for manufacturing the semiconductor device according to the embodiment;

FIGS. 14A and 14B are cross-sectional views sequentially exemplifying a part of procedures of the method for manufacturing the semiconductor device according to the embodiment; and

FIG. 15 is a schematic diagram illustrating an exemplary overall structure of a semiconductor device according to a modified example of the embodiment.

### DETAILED DESCRIPTION

A semiconductor device of an embodiment includes: a wiring board having on a surface a plurality of first electrode pads; a first semiconductor chip mounted on the wiring board, and having on a surface a plurality of second electrode pads; and a plurality of first bonding wires that individually connect the plurality of first electrode pads and the plurality of second electrode pads, the plurality of first electrode pads each having at least in a part thereof a first width in a first direction along a face of the wiring board, being arranged side by side in the first direction at a first pitch, and each having on a surface a first bump having a second width in the first direction larger than the first width; the plurality of second electrode pads being arranged side by side in the first direction at the first pitch, and the plurality of first bonding wires each being connected at one end through the first bump to each of the plurality of first electrode pads, and each being connected at another end to each of the plurality of second electrode pads.

An exemplary embodiment of this invention will be detailed below with reference to the accompanying diagrams. Note that the embodiments below by no means limit the present invention. Also note that constituents in the following embodiment include those that would be easily conceived by a person skilled in the art, or substantially identical.

### Exemplary Structure of Semiconductor Device

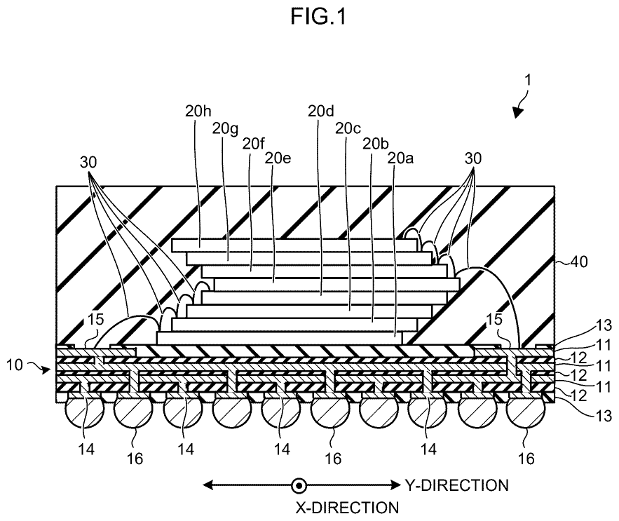

FIG. 1 is a schematic diagram illustrating an exemplary overall structure of a semiconductor device 1 according to an embodiment.

As illustrated in FIG. 1, the semiconductor device 1 of the embodiment has a wiring board 10 and a plurality of semiconductor chips 20 (20a to 20h).

The wiring board 10 has a structure in which a plurality of conductive layers 11 and a plurality of insulating layers 12 are alternatively stacked one by one. The plurality of conductive layers 11 is configured to contain a metal, such as Cu for example. The metal contained in each conductive layer 11 has a predetermined interconnect pattern. The individual conductive layers 11 are connected typically through a plurality of via holes that individually penetrate the plurality of insulating layers 12. Each insulating layer 12 is typically a prepreg formed of a resin impregnated into a fiber formed of carbon or glass, for example.

On one main face of the wiring board 10, a plurality of electrode pads 14 are provided. Each of these electrode pads 14 is provided with a solder ball 16. On the other main face of the wiring board 10, a plurality of electrode pads 15 are provided. On both faces of the wiring board 10, also solder resist layers 13 that cover portions excluding the electrode pads 14 and 15, respectively, are provided.

On the face of the wiring board 10 having the electrode pads 15 provided thereon, the plurality of semiconductor chips 20a to 20h are mounted. Each of the semiconductor chips 20a to 20h is configured to have an unillustrated semiconductor memory or the like, on each surface. Moreover, on the surface of each of the semiconductor chips 20a to 20h, there are provided electrode pads to be electrically connected to the semiconductor memory. Note that these electrode pads may be regarded as a part of the semiconductor memory.

The plurality of semiconductor chips 20a to 20h are stacked in this order on the face of the wiring board 10. From among these semiconductor chips 20a to 20h, the semiconductor chips 20a to 20d are stacked so as to be shifted stepwise, typically towards one direction along the face of the wiring board 10, which is exemplified in FIG. 1 by one side in the Y-direction. From among these semiconductor chips 20a to 20h, the semiconductor chips 20e to 20f are stacked so as to be shifted stepwise, typically towards the direction oppositely to the case of the semiconductor chips 20a to 20d, which is exemplified in FIG. 1 by the other side in the Y-direction.

That is, the plurality of semiconductor chips 20a to 20h are stacked on the wiring board 10, so as to invert the shift direction in the Y-direction between the semiconductor chips 20a to 20d and the semiconductor chips 20e to 20f.

These semiconductor chips 20 are connected thorough a plurality of bonding wires 30, while mediated by the electrode pads provided on the individual surfaces, to the electrode pads 15 on the wiring board 10.

More specifically, among the semiconductor chips 20a to 20d, connected are the semiconductor chip 20d and the semiconductor chip 20c; the semiconductor chip 20c and the semiconductor chip 20b; the semiconductor chip 20b and the semiconductor chip 20a; and, the semiconductor chip 20a and the electrode pads 15 on the wiring board 10, individually through the bonding wires 30. On the other hand, among the semiconductor chips 20e to 20h, connected are the semiconductor chip 20h and the semiconductor chip 20g; the semiconductor chip 20g and the semiconductor chip 20f; the semiconductor chip 20f and the semiconductor chip 20e; and, the semiconductor chip 20e and the electrode pads 15 on the wiring board 10, individually through the bonding wires 30.

The plurality of semiconductor chips 20 and the bonding wires 30 that connect them are covered with an encapsulation member 40 typically formed of an epoxy resin, thus being encapsulated on the wiring board 10.

In this way, the semiconductor device 1 of the embodiment is configured typically as a semiconductor package. The thus configured semiconductor device 1 is mounted typically on a mounting board of an unillustrated host computer or the like, in which various processes take place under control by the host computer.

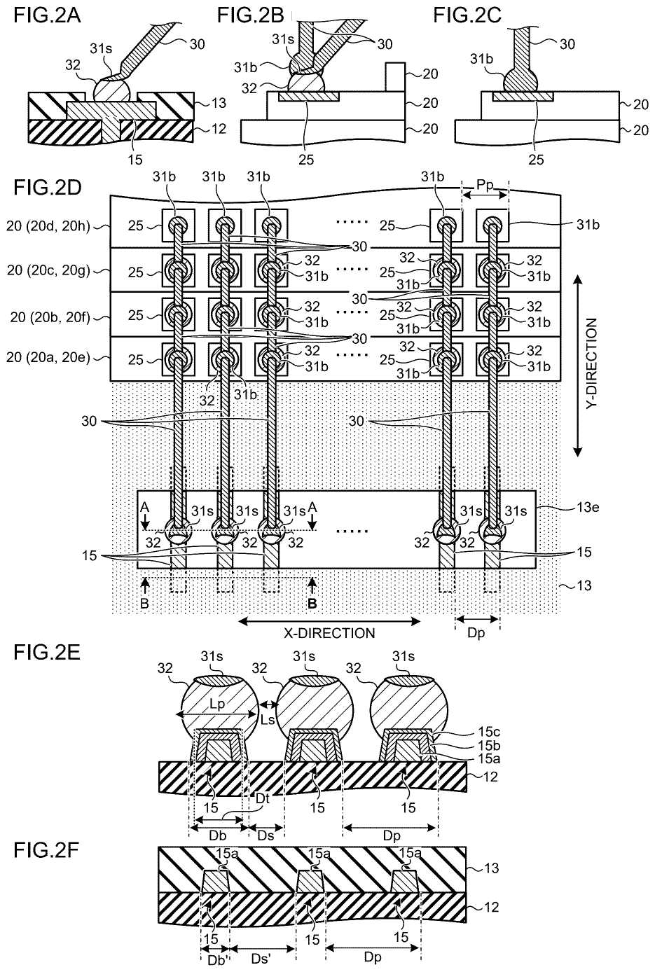

FIG. 2A to 2F are schematic diagrams illustrating connection modes between the semiconductor chips 20 and the wiring board 10 owned by the semiconductor device 1 according to the embodiment.

In more detail, FIG. 2A is an enlarged cross-sectional view of the electrode pad 15 on the wiring board 10, and FIGS. 2B and 2C are enlarged cross-sectional views of the electrode pads 25 owned by the semiconductor chips 20. FIG. 2D is a top view illustrating a part of the plurality of semiconductor chips 20 and the wiring board 10. FIGS. 2E and 2F are cross-sectional views of the electrode pad 15 on the wiring board 10, in which FIG. 2E illustrates a cross section taken along line A-A in FIG. 2D, and FIG. 2F illustrates a cross section taken along line B-B in FIG. 2D.

Note that the connection modes among the semiconductor chips 20 and the wiring board 10 illustrated in FIGS. 2A to 2F are primarily applicable to wiring used for high-speed signal transmission between the semiconductor memory in the semiconductor device 1, and an unillustrated memory controller that controls the semiconductor memory.

The memory controller is configured typically as a semiconductor chip having mounted thereon a control circuit or like, similarly to the semiconductor chip 20 having mounted thereon the semiconductor memory, and is typically mounted on the same mounting board together with the semiconductor chip 20, so as to allow various types of signal transmission to or from the semiconductor memory in the semiconductor chip 20, through the mounting board. The memory controller may be incorporated in one semiconductor package, typically in a form of mounting on the wiring board 10 on which the semiconductor chips 20 are mounted. The signal transmission, in this case, between the semiconductor memory and the memory controller may take place through the wiring board 10.

Wirings used for the high-speed signal transmission with the memory controller include signal line that transmits a signal such as data to be written into or read from the semiconductor memory; signal line that transmits a command from the memory controller to the semiconductor memory; and signal line that transmits a predetermined data address in the semiconductor memory.

Note that the connection modes among the semiconductor chips 20 and the wiring board 10 illustrated in FIGS. 2A to 2F are typically applicable to a power supply line through which power supply potential is provided to the semiconductor memory, or a ground line through which a reference potential is provided.

As illustrated in FIG. 2D, each of the plurality of semiconductor chips 20 has a plurality of electrode pads 25. The plurality of electrode pads 25 owned by each of the semiconductor chips 20 are typically arranged side by side, in a direction along the X-direction at a predetermined pitch. Pitch Pp of these electrode pads 25 is given by a sum of the width of one electrode pad 25 in the X-direction, and a space between such electrode pad 25 and an electrode pad 25 adjacent thereto in the X-direction.

Each of the plurality of electrode pads 15 on the wiring board 10 extends typically in a direction along the Y-direction. Also these electrode pads 15 are arranged side by side in a direction along the X-direction, at a predetermined pitch. Pitch Dp of these electrode pads 15 is given by a sum of the width of one electrode pad 15 in the X-direction, and a space between such electrode pad 15 and an electrode pad 15 adjacent thereto in the X-direction. The pitch Pp between the electrode pads 25 owned by each of the semiconductor chips 20, and the pitch Dp between the electrode pads 15 on the wiring board 10 are substantially equal, for example.

As described above, in a part of the solder resist layer 13 that covers the surface of the wiring board 10, there is provided an opening 13e. A part of each of the plurality of electrode pads 15 arranged in the direction along the X-direction exposes in the opening 13e of the solder resist layer 13.

The individual electrode pads 25 on the semiconductor chips 20, and the individual electrode pads 15 on the wiring board 10 are arranged at positions that mutually overlap in the Y-direction. That is, positions of the center points in the X-direction of the plurality of electrode pads 25 on the semiconductor chips 20, and positions of the center points in the X-direction of the corresponding electrode pads 15 on the wiring board 10 substantially coincide in the X-direction.

Accordingly, also the plurality of bonding wires 30 that mutually connect the electrode pads 25 on the individual semiconductor chips 20 with the electrode pads 15 on the wiring board 10 individually extend linearly in the Y-direction, in a top view.

As illustrated in FIGS. 2A and 2D, on the surface of each of the plurality of electrode pads 15 on the wiring board 10, there is provided a bump 32. Each bonding wire 30 is connected through the bump 32 to each of the electrode pads 15. In more detail, each bonding wire 30 is connected to the bump 32 on each electrode pad 15, by a technique called stitch bonding, as described later. In this way, each bonding wire 30 will have, at a connection portion with the bump 32, a stitched portion 31s shaped like a squashed bonding wire 30.

Note, although the bonding wire 30 and the bump 32 in FIGS. 2A to 2F are differently hatched for the convenience of visibility of the diagram, these components may be formed of the same material that contains metal such as Cu, Au, or Ag. Alternatively, the bump 32 may be formed with use of the bonding wire 30, as described later.

As illustrated in FIGS. 2B and 2D, also in the plurality of semiconductor chips 20 (20a to 20c, and 20e to 20g) excluding the uppermost semiconductor chip 20d from among the semiconductor chips 20a to 20d, and excluding the uppermost semiconductor chip 20h from among the semiconductor chips 20e to 20h, there are provided the bumps 32 individually on the surfaces of the plurality of electrode pads 25.

On the other hand, the bonding wire 30, whose one end is connected to the semiconductor chip 20 in the upper tier of the semiconductor chip 20 illustrated in FIG. 2B, is connected at the other end to the bump 32 on each electrode pad 25 on the semiconductor chip 20 illustrated in FIG. 2B, by stitch bonding. In this way, each bonding wire 30 will have a stitched portion 31s, at a connection portion with the bump 32 on each electrode pad 25.

Meanwhile, the bonding wire 30, whose one end is connected to the semiconductor chip 20 in the lower tier of the semiconductor chip 20 illustrated in FIG. 2B, is connected at the other end to the bump 32 on each electrode pad 25 on the semiconductor chip 20 illustrated in FIG. 2B, by a technique called ball bonding as described later. In this way, each bonding wire 30 will have a ball 31b, at a connection portion with the bump 32 on each electrode pad 25.

Note that the bonding wire 30, whose one end is connected to the semiconductor chip 20 in the lower tier, is connected to the semiconductor chip 20 illustrated in FIG. 2B, after the bonding wire 30 whose one end is connected to the semiconductor chip 20 in the upper tier, as described later. Hence on the electrode pad 25 on the semiconductor chip 20 illustrated in FIG. 2B, there are the bump 32, the stitched portion 31s of the bonding wire 30 whose one end is connected to the semiconductor chip 20 in the upper tier, and the ball 31b of the bonding wire 30 whose one end is connected to the semiconductor chip 20 in the lower tier, stacked in this order.

As described above, each of the plurality of bonding wires 30 that mutually connects the individual semiconductor chips 20, and connects the lowermost semiconductor chip 20 and the wiring board 10, has the ball 31b at one end, and the stitched portion 31s at the other end.

As illustrated in FIGS. 2C and 2D, the bonding wires 30 are directly connected, by ball bonding, to the uppermost semiconductor chip 20d from among the semiconductor chips 20a to 20d, and to the uppermost semiconductor chip 20h from among the semiconductor chips 20e to 20h. In this way, each bonding wire 30 has the ball 31b, at the connection portion with each electrode pad 25.

The bonding wires 30, whose one ends having the ball 31b are connected to the uppermost semiconductor chips 20d and 20h, are respectively connected to the semiconductor chips 20c and 20g one tier below, at the other ends having the stitched portions 31s.

As illustrated in FIG. 2E, each of the plurality of electrode pads 15 exposed in the opening 13e of the solder resist layer 13 has a core layer 15a configured to contain Cu or the like; and a plating layer 15b and a plating layer 15c that sequentially cover the core layer 15a. The plating layer 15b is typically a Ni layer, and the plating layer 15c is typically an Au layer.

The core layer 15a of the electrode pad 15 has a tapered shape whose width in the X-direction increases from the side the bump 32 is arranged, towards the side in contact with the uppermost insulating layer 12 of the wiring board 10. Therefore, also the electrode pad 15, with the thus-shaped core layer 15a covered with the plating layers 15b and 15c, will have a tapered shape whose width Db at the lower end is wider than width Dt at the upper end, in a direction along the X-direction.

The width Db at the lower end of the electrode pad 15 is typically 10 μm or wider and 60 μm or narrower. Distance Ds between the lower ends of the electrode pads 15 adjacent in the X-direction is typically 10 μm or longer and 80 μm or shorter. Therefore, the aforementioned pitch Dp between the electrode pads 15 is given by a sum of the width Db at the lower end of the electrode pad 15, and the distance Ds between the lower ends of the electrode pads 15.

On the other hand, the bump 32 arranged on the electrode pad 15 has a maximum width Lp, in the X-direction, of typically 15 μm or wider and 70 μm or narrower, more preferably 16 μm or wider and 66 μm or narrower, which is larger than the width Db at the lower end of the electrode pad 15. Moreover, distance Ls between the bumps 32, arranged on the electrode pads 15 adjacent in the X-direction, is typically larger than 4 μm. Now, the distance Ls represents a distance measured at a maximum width Lp portion of the bump 32, that is, a distance of a part where the bumps 32 are most proximal to each other.

With the electrode pad 15 having finely designed width Dt and Db respectively at the upper and lower ends, and with the bumps 32 having the maximum width Lp larger than the electrode pad 15 arranged thereon, it now becomes possible to connect the bonding wire 30 to the bump 32 with a sufficient level of bond strength, thus enabling electrical connection of the bonding wire 30 with the electrode pad 15, through the bump 32.

Note that in the process of connecting the bonding wire 30 onto the bump 32 by the stitch bonding, the bump 32 may be slightly squashed at the top end as described later, since the bonding wire 30 is pressed against the bump 32.

Portions of the electrode pads 15 arranged in the opening 13e of the solder resist layer 13, and the bumps 32 arranged on the exposed portions of the electrode pads 15 are covered with the encapsulation member 40. In this case where the distance Ds between the electrode pads 15 and the distance Ls between the bumps 32 are thus designed as described above, withstand voltage will become sufficiently high between the adjacent electrode pads 15, and between the adjacent bumps 32.

As illustrated in FIG. 2F, portions of the plurality of electrode pads 15 covered with the solder resist layer 13 typically have the core layer 15a only, without being covered with the plating layers 15b and 15c. Therefore, the width Db′ at the lower end of each electrode pad 15 in this portion is narrower than the width Db illustrated in the aforementioned FIG. 2E, and, the distance Ds′ between the lower ends of the electrode pads 15 in this portion is wider than the distance Ds illustrated in the aforementioned FIG. 2E. Note, the pitch Dp between the electrode pads 15, that is, the sum of the width Db′ at the lower end of the electrode pad 15 and the distance Ds′ between the lower ends of the electrode pads 15 in this portion, is substantially equal to the pitch Dp illustrated in FIG. 2E.

When voltage is applied in a highly humid environment to the electrode pads 15 used for transmission of various signals, the solder resist layer 13 would be hydrolyzed, whereby Cu or the like in the core layers 15a of the electrode pads 15 become more likely to migrate. Now with the distance Ds between the electrode pads 15 thus designed, the adjacent electrode pads 15 are prevented from being electrically connected or from short-circuiting, due to displaced Cu or the like as a result of migration.

The electrode pads 15 are likely to be formed typically with the tapered shape as described above. The electrode pads 15 are therefore configured while adjusting the line width, so that the distance Ds left between the electrode pads 15, while assuming the maximum width in the X-direction of the electrode pad 15 as the width Db at the lower end, will be fully suppressive against the short-circuiting due to migration or the like, and are arranged at a narrow pitch in accordance with the pitch of the electrode pads 25 on the semiconductor chips 20. On the other hand, since the width Dt at the upper end of the electrode pad 15, which serves as a connection portion with the bonding wire 30, will become further narrower than the width Db at the lower end, so that the bonding wire 30 is connected after placing in between the bump 32 having the width larger than that of the electrode pad 15, so as to obtain a sufficient level of bond strength with the bonding wire 30.

### Method for Manufacturing Semiconductor Device

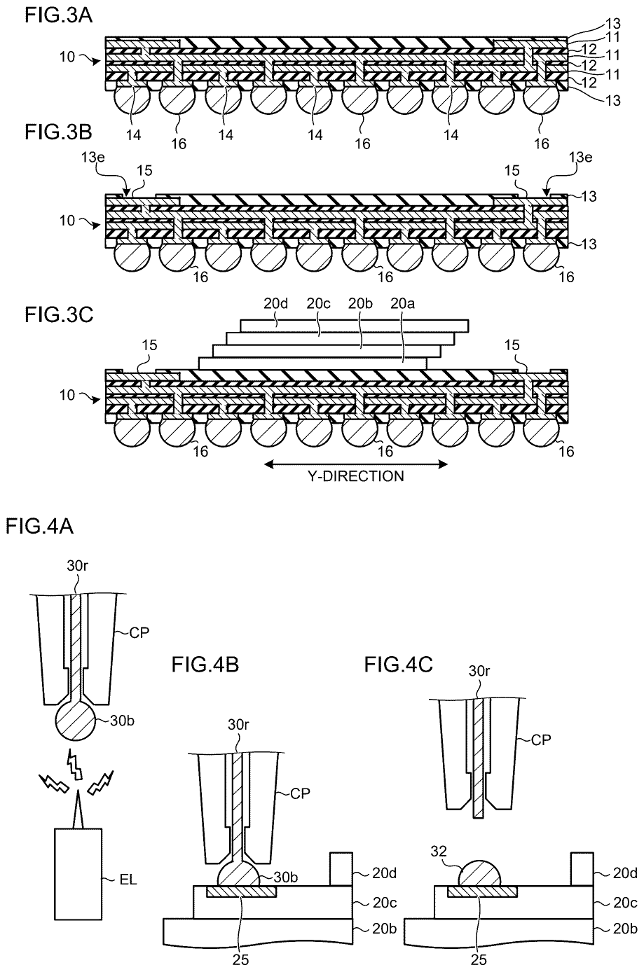

Next, a method for manufacturing the semiconductor device 1 according to the embodiment will be explained, referring to FIGS. 3A to 14C.

FIGS. 3A to 14C are diagrams sequentially exemplifying a part of procedures of the method for manufacturing the semiconductor device 1 according to the embodiment.

As illustrated in FIG. 3A, the wiring board 10 is prepared. The wiring board 10 is typically formed by alternately stacking the plurality of conductive layers 11 and the plurality of insulating layers 12 one by one, and by covering the upper and lower faces with the solder resist layer 13. In the process of alternately stacking the conductive layers 11 and the insulating layers 12, each conductive layer 11 is formed as having an interconnect pattern. The interconnect pattern of the conductive layer 11 is formed typically by a subtractive method, or an additive method.

In the subtractive method, the sheet-like conductive layer 11 is stacked on the insulating layer 12, and the conductive layer 11 is etched according to a predetermined pattern, thereby forming the interconnect pattern. In the additive method, a seed layer formed on the insulating layer 12 is covered with a resist pattern, and the seed layer exposed from the resist pattern is plated with Cu, thereby forming the interconnect pattern.

The additive method further includes several method such as semi-additive process (SAP) method, or modified semi-additive process (MSAP) method. In the SAP method, the seed layer is formed by electroless plating, or sputtering. In the MSAP method, the seed layer is formed by laminating a metal foil onto the insulating layer.

Any method including the subtractive method and the additive method can form the wiring board 10 at a relatively low cost.

Thereafter, a part of the solder resist layer 13 on one face of the wiring board 10 is removed to expose the plurality of electrode pads 14, and the solder balls 16 are individually formed on the electrode pads 14 typically by a reflow process.

As illustrated in FIG. 3B, the opening 13e is formed in the solder resist layer 13 on a face on the other side of the wiring board 10, to expose therein the plurality of electrode pads 15. The exposed portions of the plurality of electrode pads 15 are then sequentially subjected to Ni plating, Au plating or the like, thereby covering the core layer 15a formed of Cu or the like, with the plating layers 15b and 15c.

As illustrated in FIG. 3C, the plurality of semiconductor chips 20a to 20d are stacked on the wiring board 10 in this order, while being shifted to one side in the Y-direction.

Thereafter, the semiconductor chips 20a to 20d and the wiring board 10 are connected with the bonding wires 30, sequentially from any of the semiconductor chips 20 in the upper tier. At this time, processes including formation of the bumps 32, ball bonding, and stitch bonding are repeated as described above. Hereinafter, details of a bonding technique with the bonding wires 30 will be illustrated in FIGS. 4A to 6F.

As described above, the connection with the bonding wires 30 proceeds sequentially from any of the semiconductor chips 20 in the upper tier. Meanwhile, on the semiconductor chip 20 which serves as a connection target for the bonding wire 30, that is, on the semiconductor chip 20 in the lower tier out of two semiconductor chips 20 to be connected, there is the bump 32 having been formed in advance of the connection with the bonding wire 30.

FIGS. 4A to 4C illustrate situations in the process of connecting the uppermost semiconductor chip 20d to the semiconductor chip 20c one tier below, where the bump 32 is formed on the electrode pad 25 on the semiconductor chip 20c in the lower tier, which serves as a connection target for the bonding wire 30.

As illustrated in FIG. 4A, a wire 30r which serves as a material for the bonding wire 30 is allowed to pass through a capillary CP, and a spherical ball 30b is then formed at the end of the wire 30r under arc discharge with use of an electrode EL.

As illustrated in FIG. 4B, the capillary CP is then brought close to the semiconductor chip 20c, and the ball 30b formed at the end of the wire 30r is brought into contact with the electrode pad 25 on the semiconductor chip 20c. The contact portion between the ball 30b and the electrode pad 25 is then heated, and the ball 30b is bonded to the electrode pad 25 by ultrasonic bonding.

As illustrated in FIG. 4C, the capillary CP is elevated from the proximity of the electrode pad 25 on the semiconductor chip 20c, thereby separating the ball 30b bonded to the electrode pad 25 from the wire 30r. In this way, the bump 32 is formed on the electrode pad 25 on the semiconductor chip 20c.

As described above, the connection method with use of the bonding wire 30 includes ball bonding and stitch bonding. In a process of mutually connecting the semiconductor chips 20 with use of the bonding wire 30, the semiconductor chip 20 as a connection source and the bonding wire 30 are connected by ball bonding. On the other hand, the semiconductor chip 20 as a connection target and the bonding wire 30 are connected by stitch bonding.

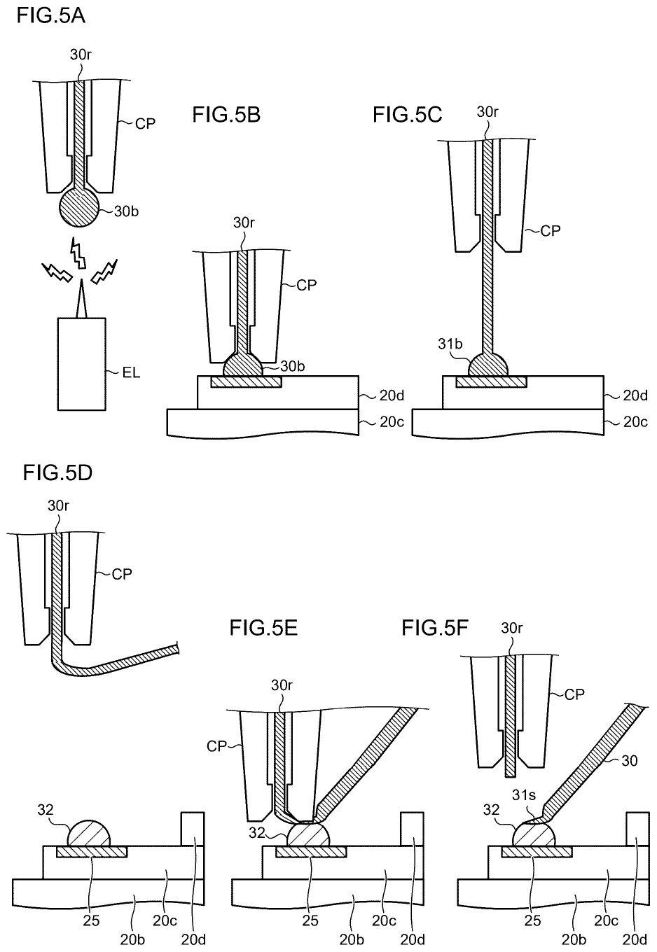

FIGS. 5A to 5F illustrate situations of mutually connecting the uppermost semiconductor chip 20d and the semiconductor chip 20c one tier below, with use of the bonding wire 30.

As illustrated in FIG. 5A, the ball 30b is formed at the end of the wire 30r having been passed through the capillary CP, under arc discharge with use of the electrode EL, similarly to as illustrated in FIG. 4A. Note, although the wire 30r, the ball 30b and the like in FIGS. 5A to 5F are hatched differently from those in FIGS. 4A to 4C for the convenience of visibility of the diagram, same materials may be used for the processes in FIGS. 4A to 4C, and for the processes in FIGS. 5A to 5F.

As illustrated in FIG. 5B, the ball 30b formed at the end of the wire 30r is pressed under the tip of the capillary CP, against the electrode pad 25 on the semiconductor chip 20c, followed by heating and ultrasonic bonding.

As illustrated in FIG. 5C, the capillary CP is elevated from the electrode pad 25 on the semiconductor chip 20c. In this process, by elevating the capillary CP while feeding the wire 30r forward, the ball 31b that stays connected with the wire 30r is formed on the electrode pad 25, without being separated from the wire 30r.

As illustrated in FIG. 5D, the capillary CP is moved above the semiconductor chip 20c in the lower tier, while further feeding the wire 30r forward. In this process, a route of movement of the capillary CP is controlled so that the wire 30r, having been connected at one end to the semiconductor chip 20d in the upper tier, will arrive above the semiconductor chip 20c in the lower tier, while appropriately shaped into a loop.

As illustrated in FIG. 5E, the capillary CP is lowered, and the wire 30r, with the one end extended towards the uppermost semiconductor chip 20d, is caught at a portion immediately after being drawn out from the capillary CP, between the bump 32 on the semiconductor chip 20c and the capillary CP, and then squashed under the tip of the capillary CP. The contact portion between the wire 30r and the bump 32 is concurrently heated, and the wire 30r and the bump 32 are bonded by ultrasonic bonding.

As illustrated in FIG. 5F, the capillary CP is then elevated, to cut off the wire 30r bonded on the bump 32. In this process, under shearing force effected on the squashed portion of the wire 30r, such wire 30r having been bonded on the bump 32 will have the stitched portion 31s formed at the end.

In this way, the bonding wire 30, with the one end connected to the semiconductor chip 20d in the upper tier, and with the other end connected to the bump 32 on the semiconductor chip 20c, may be formed.

Also thereafter, the individual semiconductor chips 20 are mutually connected with use of the bonding wire 30, by repeating formation of the bump 32 on each of the semiconductor chips 20 in the lower tier, ball bonding to each of the semiconductor chips 20 in the upper tier, and stitch bonding to each of the semiconductor chips 20 in the lower tier.

Now on the semiconductor chips 20 in the upper tiers, excluding the uppermost semiconductor chip 20d, the bonding wire 30 is connected by ball bonding, while being mediated by the electrode pad 25, the bump 32, and the stitched portion 31s on the bump 32.

Note that the stitched portion 31s on the bump 32 is provided at the other end of the bonding wire 30 whose one end has been connected to the semiconductor chip 20 in the upper tier of this semiconductor chip 20. Also note that the bonding wire 30 to be newly connected to the semiconductor chip 20, by ball bonding, is allowed for connection of this semiconductor chip 20, with the semiconductor chip 20 further in the lower tier.

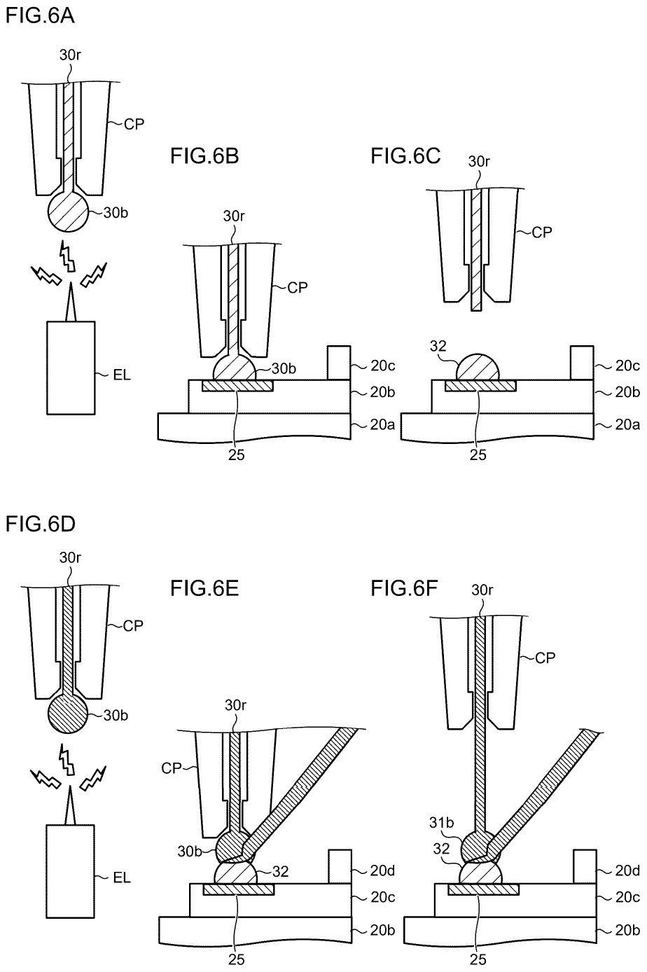

FIGS. 6A to 6F illustrate situations in the process of connecting the semiconductor chip 20b and the bonding wire 30, by ball bonding.

As illustrated in FIG. 6A, the ball 30b is formed at the end of the wire 30r having been passed through the capillary CP, under arc discharge with use of the electrode EL.

As illustrated in FIG. 6B, the ball 30b formed at the end of the wire 30r is brought into contact with the electrode pad 25 on the semiconductor chip 20b, followed by heating and ultrasonic bonding.

As illustrated in FIG. 6C, the capillary CP is elevated so as to cut off the ball 30b, having been bonded to the electrode pad 25 on the semiconductor chip 20b, from the wire 30r, thereby forming the bump 32 on the electrode pad 25.

As illustrated in FIG. 6D, the ball 30b is formed at the end of the wire 30r having been passed through the capillary CP, under arc discharge with use of the electrode EL.

As illustrated in FIG. 6E, the capillary CP is lowered onto the bump 32 on the semiconductor chip 20c, and the ball 30b at the end of the wire 30r is pressed against the bump 32 on the semiconductor chip 20c, while placing in between the stitched portion 31s of the bonding wire 30 having been connected to the semiconductor chip 20d.

As illustrated in FIG. 6F, the capillary CP is elevated while feeding the wire 30r forward, thereby forming the ball 31b that stays connected with the wire 30r, on the bump 32 on the semiconductor chip 20c.

Thereafter, the other end of the wire 30r, having the ball 31b at one end, will be connected to the semiconductor chip 20b by stitch bonding.

Also, the semiconductor chip 20b and the semiconductor chip 20a are connected in the same manner, and also connection of the lowermost semiconductor chip 20a to the wiring board 10 proceeds by way of formation of the bump 32 on the wiring board 10, ball bonding onto the semiconductor chip 20a, and stitch bonding onto the wiring board 10.

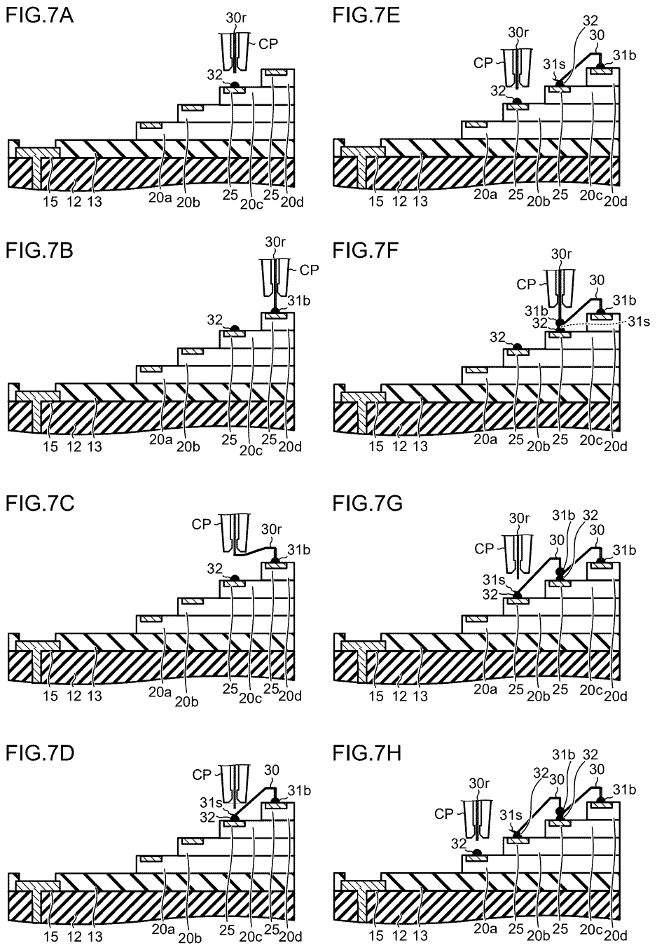

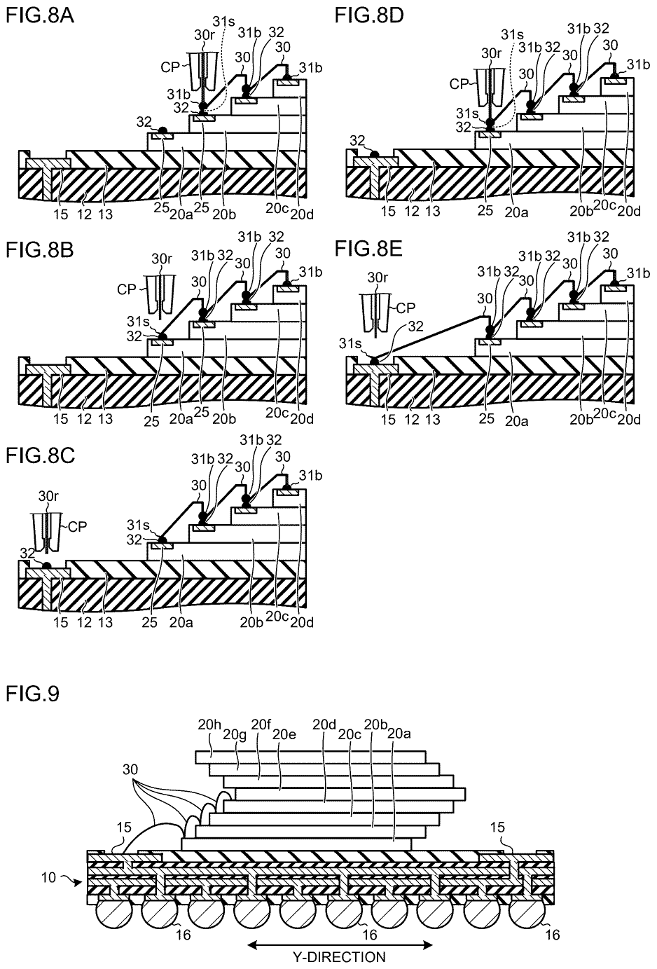

The overall situations of the aforementioned connection method of the semiconductor chips 20a to 20d and the wiring board 10 will be summarized again in FIGS. 7A to 8E below.

As illustrated in FIG. 7A, the bump 32 is formed on the electrode pad 25 on the semiconductor chip 20c.

As illustrated in FIG. 7B, ball bonding is directed to the electrode pad 25 on the semiconductor chip 20d to connect the ball 31b.

As illustrated in FIG. 7C, the capillary CP is moved from the semiconductor chip 20d to the semiconductor chip 20c along a predetermined route, so that the wire 30r having been connected to the semiconductor chip 20d will be appropriately shaped into a loop.

As illustrated in FIG. 7D, stitch bonding is directed to the bump 32 on the semiconductor chip 20c, to form the bonding wire 30 which is connected to the semiconductor chip 20d through the ball 31b, and connected to the semiconductor chip 20c through the stitched portion 31s.

As illustrated in FIG. 7E, the bump 32 is formed on the electrode pad 25 on the semiconductor chip 20b.

As illustrated in FIG. 7F, ball bonding is directed through the stitched portion 31s to the bump 32 on the semiconductor chip 20c, to connect the ball 31b.

As illustrated in FIG. 7G, stitch bonding is directed to the bump 32 on the semiconductor chip 20b, to form the bonding wire 30 which is connected to the semiconductor chip 20c through the ball 31b, and connected to the semiconductor chip 20b through the stitched portion 31s.

As illustrated in FIG. 7H, the bump 32 is formed on the electrode pad 25 on the semiconductor chip 20a.

As illustrated in FIG. 8A, ball bonding is directed through the stitched portion 31s to the bump 32 on the semiconductor chip 20b, to connect the ball 31b.

As illustrated in FIG. 8B, stitch bonding is directed to the bump 32 on the semiconductor chip 20a, to form the bonding wire 30 which is connected to the semiconductor chip 20b through the ball 31b, and connected to the semiconductor chip 20a through the stitched portion 31s.

As illustrated in FIG. 8C, the bump 32 is formed on the electrode pad 15 on the wiring board 10.

As illustrated in FIG. 8D, ball bonding is directed through the stitched portion 31s to the bump 32 on the semiconductor chip 20a, to connect the ball 31b.

As illustrated in FIG. 8E, stitch bonding is directed to the bump 32 on the wiring board 10, to form the bonding wire 30 which is connected to the semiconductor chip 20a through the ball 31b, and connected to the wiring board 10 through the stitched portion 31s.

In this way, the semiconductor chips 20a to 20d and the wiring board 10 are mutually connected by the plurality of bonding wires 30.

As illustrated in FIG. 9, the plurality of semiconductor chips 20e to 20h are stacked on the semiconductor chips 20a to 20d in this order, while being shifted to one side in the Y-direction.

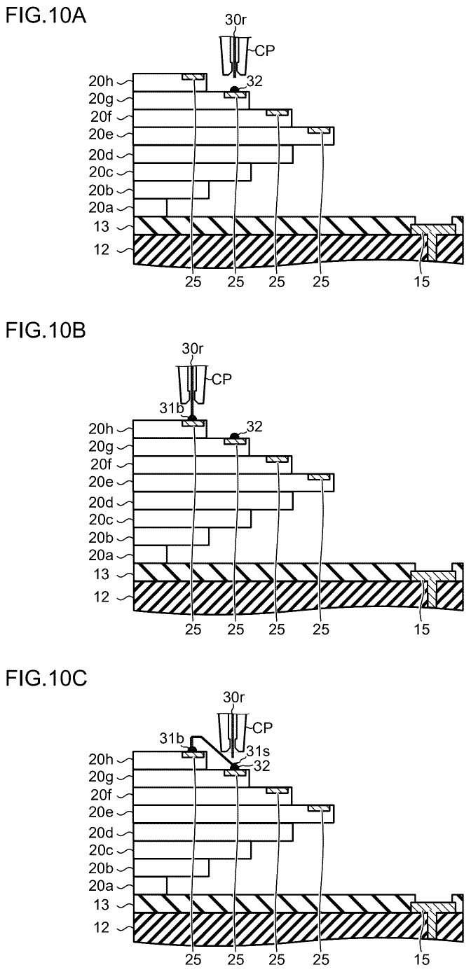

Thereafter, the semiconductor chips 20e to 20h and the wiring board 10 are connected with the bonding wires 30, sequentially from any of the semiconductor chips 20 in the upper tier. The situations will be illustrated in FIGS. 10A to 13C.

As illustrated in FIG. 10A, the bump 32 is formed on the electrode pad 25 on the semiconductor chip 20g.

As illustrated in FIG. 10B, ball bonding is directed to the electrode pad 25 on the semiconductor chip 20h to connect the ball 31b.

As illustrated in FIG. 10C, stitch bonding is directed to the bump 32 on the semiconductor chip 20g, to form the bonding wire 30 which is connected to the semiconductor chip 20h through the ball 31b, and connected to the semiconductor chip 20g through the stitched portion 31s.

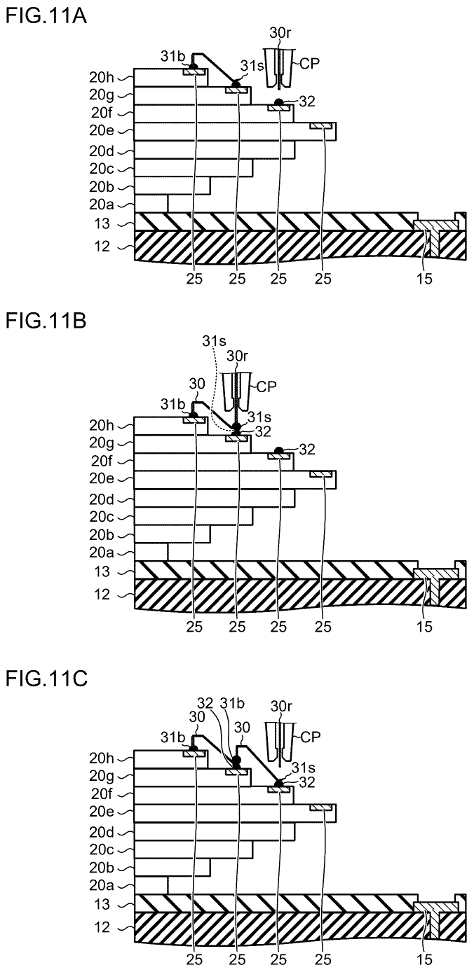

As illustrated in FIG. 11A, the bump 32 is formed on the electrode pad 25 on the semiconductor chip 20f.

As illustrated in FIG. 11B, ball bonding is directed through the stitched portion 31s to the bump 32 on the semiconductor chip 20g, to connect the ball 31b.

As illustrated in FIG. 11C, stitch bonding is directed to the bump 32 on the semiconductor chip 20f, to form the bonding wire 30 which is connected to the semiconductor chip 20g through the ball 31b, and connected to the semiconductor chip 20f through the stitched portion 31s.

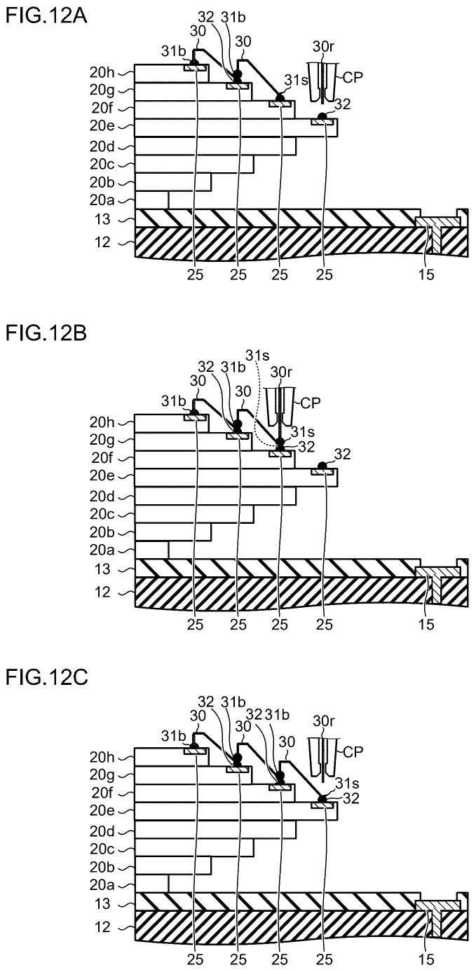

As illustrated in FIG. 12A, the bump 32 is formed on the electrode pad 25 on the semiconductor chip 20e.

As illustrated in FIG. 12B, ball bonding is directed through the stitched portion 31s to the bump 32 on the semiconductor chip 20f, to connect the ball 31b.

As illustrated in FIG. 12C, stitch bonding is directed to the bump 32 on the semiconductor chip 20e, to form the bonding wire 30 which is connected to the semiconductor chip 20f through the ball 31b, and connected to the semiconductor chip 20e through the stitched portion 31s.

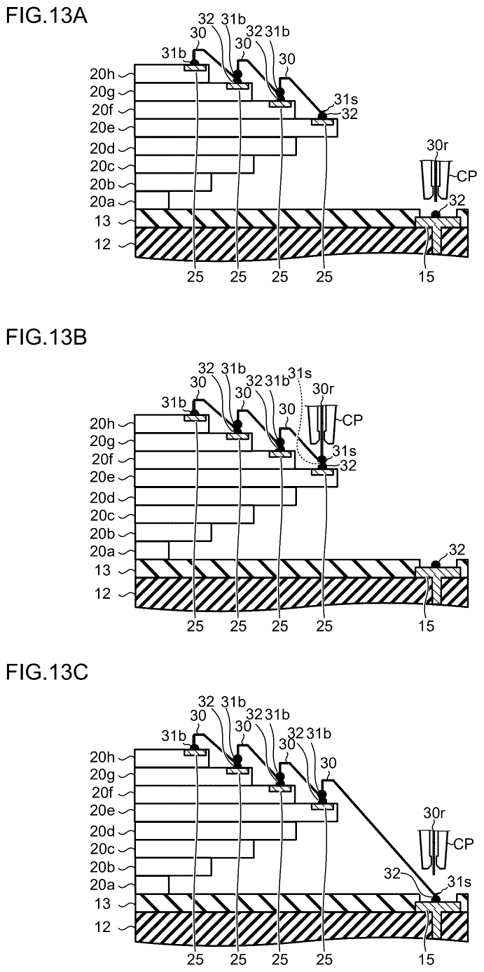

As illustrated in FIG. 13A, the bump 32 is formed on the electrode pad 15 on the wiring board 10.

As illustrated in FIG. 13B, ball bonding is directed through the stitched portion 31s to the bump 32 on the semiconductor chip 20e, to connect the ball 31b.

As illustrated in FIG. 13C, stitch bonding is directed to the bump 32 on the wiring board 10, to form the bonding wire 30 which is connected to the semiconductor chip 20e through the ball 31b, and connected to the wiring board 10 through the stitched portion 31s.

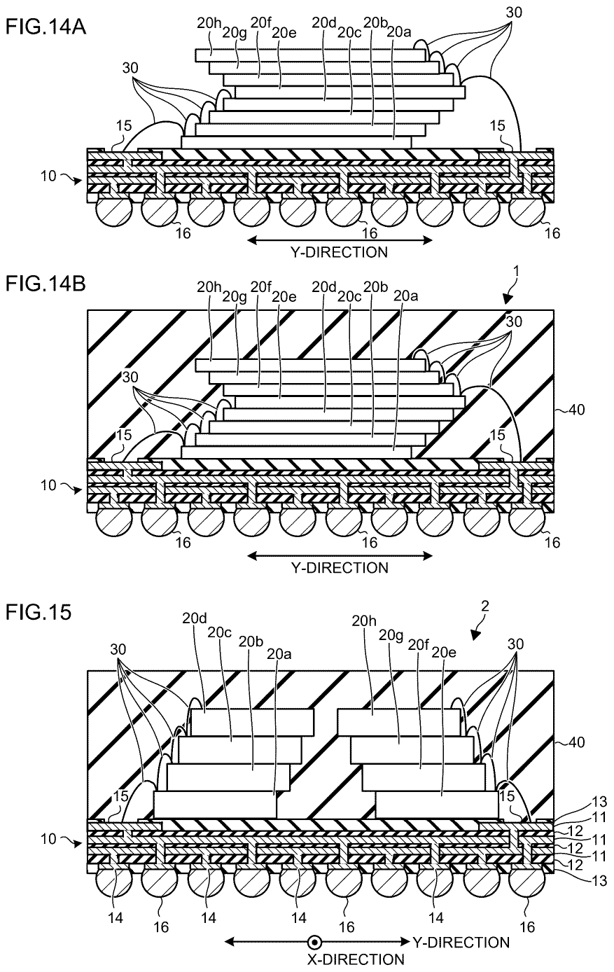

In this way, as illustrated in FIG. 14A, the semiconductor chips 20e to 20h and the wiring board 10 are mutually connected by the plurality of bonding wires 30.

As illustrated in FIG. 14B, the semiconductor chips 20a to 20h, the plurality of bonding wires 30 and the like are covered with the encapsulation member 40, thereby encapsulating these structures on the wiring board 10.

In this way, the semiconductor device 1 according to the embodiment is manufactured.

### SUMMARY

In a semiconductor chip having semiconductor memory or the like mounted therein, various signals are transmitted to and from a memory controller, while mediated by the wiring board. For high-speed transmission of signals such as data, command, and address, it is desirable to minimize as possible the length of the bonding wire that connects the semiconductor chip and the wiring board. In this case, if the electrode pads on the wiring board are arranged at a pitch larger than that of the electrode pads on the semiconductor chip, the positions in the X-direction of these pads are misaligned, thus needing the bonding wire to be extended diagonally from the electrode pad on the semiconductor chip, and thus elongating the bonding wire.

On the other hand, if the electrode pads on the wiring board were arranged at a narrow pitch, there is a concern that short-circuiting would occur between adjacent electrode pads due to migration of Cu or the like that constitutes the electrode pads. Shrinkage of the line width of the electrode pads, intended for widening the space between the electrode pads while maintaining the narrow pitch of the electrode pads, would fail in obtaining a sufficient level of bond strength with the bonding wire.

In the semiconductor device 1 of the embodiment, each of the plurality of electrode pads 15 on the wiring board 10 has, arranged on the surface thereof, the bump 32 having a width in the X-direction larger than the width of each electrode pad 15. Accordingly, even under narrowed width of the electrode pads 15 in the X-direction, a sufficient level of bond strength of the bonding wire 30 is obtainable, by way of bonding onto the bump 32. The electrode pads 15 on the wiring board 10 may, therefore, be arranged at a narrow pitch, while narrowing the electrode pads 15 in the X-direction so as to suppress short-circuiting between the electrode pads 15, whereby the length of wiring between the wiring board 10 and the semiconductor chips 20 may be shortened.

In the semiconductor device 1 of the embodiment, the plurality of electrode pads 15 on the wiring board 10 are arranged individually at positions that overlap with the plurality of electrode pads 25 on the semiconductor chip 20, in a direction along the Y-direction. In this way, the bonding wire 30 may be extended typically with a shortest distance in a direction along the Y-direction in a top view, to connect the wiring board 10 and the semiconductor chips 20. The length of wiring between the wiring board 10 and the semiconductor chips 20 may therefore be shortened.

In the semiconductor device 1 of the embodiment, and in the plurality of electrode pads 15 on the wiring board 10, the width in the X-direction at the lower end opposed to the face of the wiring board 10, is larger than the width in the X-direction at the upper end on which the bump 32 is arranged. Even if the electrode pad 15 has been typically tapered in this way, a sufficient level of bond strength may be maintained at the upper end of the electrode pad 15 having a narrower width Dt, by connecting the bonding wire 30 while placing the bump 32 in between.

In the semiconductor device 1 of the embodiment, the distance Ds between the lower ends of the plurality of electrode pads 15 in the X-direction is 10 μm or longer and 80 μm or shorter. In this way, the short-circuiting between the electrode pads 15 may be suppressed.

In the semiconductor device 1 of the embodiment, the space in the X-direction between the bumps 32, owned by the electrode pads 15 adjacent in the X-direction, is wider than 4 μm. In this way, the bumps 32 adjacent in the X-direction are prevented from contacting.

### Modified Example

In the aforementioned embodiment, the semiconductor device 1 was structured to have the plurality of semiconductor chips 20 stacked in multiple tiers. Arrangement of the semiconductor chips 20 on the wiring board 10 is, however, not limited to that exemplified in the aforementioned embodiment. The plurality of semiconductor chips 20 may be divided into two or more groups, and may be individually stacked on the wiring board 10. Alternatively, the plurality of semiconductor chips 20 may be stacked while being shifted in a direction other than the Y-direction, for example in the X-direction. FIG. 15 illustrates an exemplary case where the plurality of semiconductor chips 20 are arranged differently from the aforementioned embodiment.

FIG. 15 is a schematic diagram illustrating an exemplary overall structure of a semiconductor device 2, according to a modified example of the embodiment.

As illustrated in FIG. 15, from among the plurality of semiconductor chips 20a to 20h mounted on the wiring board 10, the semiconductor chips 20a to 20d are stacked in this order on the top face of the wiring board 10, while being shifted to one side in the Y-direction. On the other hand, the semiconductor chips 20e to 20h are stacked in this order on the top face of the wiring board 10, while being shifted towards the other side in the Y-direction.

A connection mode same as that in the aforementioned embodiment is also applicable to the thus arranged semiconductor chips 20a to 20h, for connection with the wiring board 10.

The semiconductor device 2 of the modified example can demonstrate the same effects as the semiconductor device 1 of the aforementioned embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a wiring board having on a surface a plurality of first electrode pads;
a first semiconductor chip mounted on the wiring board, and having on a surface a plurality of second electrode pads; and
a plurality of first bonding wires that individually connect the plurality of first electrode pads and the plurality of second electrode pads,
the plurality of first electrode pads:
each having at least in a part thereof a first width in a first direction along a face of the wiring board;
being arranged side by side in the first direction at a first pitch; and
each having on a surface a first bump having a second width in the first direction larger than the first width,
the plurality of second electrode pads being arranged side by side in the first direction at the first pitch, and,
the plurality of first bonding wires:
each being connected at one end through the first bump to each of the plurality of first electrode pads; and
each being connected at another end to each of the plurality of second electrode pads.

2. The semiconductor device according to claim 1, wherein
the plurality of first electrode pads are arranged individually at positions that overlap with the plurality of second electrode pads, in a second direction that extends along the face of the wiring board and intersects the first direction.

3. The semiconductor device according to claim 2, wherein
a position of a center point in the first direction of each of the plurality of first electrode pads and a position of a center point in the first direction of each of the plurality of second electrode pads substantially coincides in the second direction.

4. The semiconductor device according to claim 1, wherein
the first width of each of the plurality of first electrode pads is a maximum width in the first direction of the plurality of first electrode pads.

5. The semiconductor device according to claim 4, wherein,
in the plurality of first electrode pads, a width in the first direction of a first face, on a side opposed to the face of the wiring board, is larger than a width in the first direction of a second face on which the first bump is arranged, and,
the first width of each of the plurality of first electrode pads is the width in the first direction of the first face.

6. The semiconductor device according to claim 5, wherein
in a view on the first face, the plurality of first electrode pads have a space in between in the first direction of 10 μm or wider and 80 μm or narrower.

7. The semiconductor device according to claim 6, wherein
a space in the first direction between the first bumps on the first electrode pads adjacent in the first direction from among the plurality of first electrode pads, is wider than 4μm.

8. The semiconductor device according to claim 6, wherein
the first width is 10 μm or wider and 60 μm or narrower, and,
the second width is 15 μm or wider and 70 μm or narrower.

9. The semiconductor device according to claim 1, wherein
the wiring board has a solder resist layer that covers the plurality of first electrode pads excluding an arrangement area of the first bumps,
the first semiconductor chip is encapsulated on the wiring board with an encapsulation member,
in the arrangement area of the first bumps, the plurality of first electrode pads are covered with the encapsulation member, together with the first bumps having a first space in between in the first direction, while keeping a second space in between wider than the first space in the first direction; and
in an area excluding the arrangement area of the first bumps, the plurality of first electrode pads are covered with the solder resist layer, while keeping a third space in between wider than the second space in the first direction.

10. A semiconductor device according claim 1, further comprising
one or more second semiconductor chips stacked above the first semiconductor chip, each having a plurality of third electrode pads,
the one or more second semiconductor chips are arranged, relative to the first semiconductor chip, in a second direction that extends along the face of the wiring board and intersects the first direction, so as to depart from the plurality of first electrode pads,
the plurality of third pads are arranged on each of the one or more second semiconductor chips, side by side in the first direction at the first pitch,
each of the plurality of second electrode pads has on a surface a second bump,
each of the plurality of third electrode pads on a lowermost second semiconductor chip, from among the one or more second semiconductor chips,
has on a surface a third bump, and
is connected to each of the plurality of second electrode pads, with a plurality of second bonding wires each connected at one end through the second bump to each of the plurality of second electrode pads, and connected at another end through the third bump to each of the plurality of third electrode pads on the lowermost second semiconductor chip.

11. The semiconductor device according to claim 10, wherein
from among the one or more second semiconductor chips, each of the plurality of third electrode pads on an uppermost second semiconductor chip is connected to each of the plurality of third electrode pads on a second semiconductor chip one tier below, with a plurality of third bonding wires each connected at one end through the third bump to each of the plurality of third electrode pads on the second semiconductor chip one tier below, and is directly connected at another end to each of the plurality of third electrode pads on the uppermost second semiconductor chip.

12. The semiconductor device according to claim 1, wherein
the first semiconductor chip is a memory chip on which a semiconductor memory is mounted, and,
at least a part of the plurality of first bonding wires is a signal line that transmits data with a memory controller that controls the semiconductor memory.

13. The semiconductor device according to claim 1, wherein
the first semiconductor chip is a memory chip on which a semiconductor memory is mounted, and,
at least a part of the plurality of first bonding wires is a signal line that transmits data address in the semiconductor memory, with a memory controller that controls the semiconductor memory.

14. The semiconductor device according to claim 1, wherein
the first semiconductor chip is a memory chip on which a semiconductor memory is mounted, and,
at least a part of the plurality of first bonding wires is a signal line that transmits a command directed to the semiconductor memory, with a memory controller that controls the semiconductor memory.

15. The semiconductor device according to claim 1, wherein
the first semiconductor chip is a memory chip on which a semiconductor memory is mounted, and,
at least a part of the plurality of first bonding wires is a power source line that supplies electric power to the semiconductor memory.

16. The semiconductor device according to claim 1, wherein
the first semiconductor chip is a memory chip on which a semiconductor memory is mounted, and,
at least a part of the plurality of first bonding wires is a ground line that gives a reference potential to the semiconductor memory.
